(19) United States
(12) Patent Application Publication
(10) Pub. No.: US 2022/0093565 A1
(43) Pub. Date: Mar. 24, 2022

(54) STACKED DIE AND VR CHIPLET WITH DUAL-SIDED AND UNIDIRECTIONAL CURRENT FLOW

(71) Applicant: Intel Corporation, Santa Clara, CA (US)

(72) Inventors: Kaladhar RADHAKRISHNAN, Chandler, AZ (US); Krishna BHARATH, Phoenix, AZ (US)

(21) Appl. No.: 17/031,819

(22) Filed: Sep. 24, 2020

(51) Int. Cl. H01L 25/065; H01L 49/02; H01L 23/00; H01L 23/64

(52) U.S. Cl. CPC H01L 25/0657; H01L 28/10; H01L 24/16; H01L 23/645; H01L 2225/06513; H01L 2924/19103; H01L 2225/06531; H01L 2224/16227; H01L 2924/1427; H01L 2924/19042; H01L 2225/06517

(57) ABSTRACT

Embodiments disclosed herein include voltage regulators VR integrated into an electronic device. In an embodiment, an electronic device comprises a package substrate, a first die electrically coupled to the package substrate, and a second die with a first surface facing the first die and second surface facing the package substrate that is electrically coupled to the package substrate and the first die. In an embodiment, the second die is between the package substrate and the first die. In an embodiment, the second die comprises voltage regulation (VR) circuitry. In an embodiment current is received by the second die through only the first surface and the current only exits the second die through the second surface.

### TECHNICAL FIELD

Embodiments of the present disclosure relate to semiconductor devices, and more particularly to voltage regulator (VR) chiplets that have unidirectional current flow.

### BACKGROUND

In fully integrated voltage regulator (FIVR) and other integrated voltage regulator (IVR) architectures, the area allocated for the necessary circuitry for the VR is typically much smaller than the minimum bump area required to meet the Iₘₐₓ requirements. When the IVR is integrated on the main die (e.g., a system-on-a-chip (SoC)), die area impact is limited by repurposing bumps from neighboring logic blocks. However, when the IVR is disaggregated from the SoC, there are no neighboring logic blocks. As such, the footprint of the IVR chiplet needs to be increased in order to supply the necessary bumps to meet Iₘₐₓ requirements.

### BRIEF DESCRIPTION OF THE DRAWINGS

FIG. 1 is a cross-sectional illustration of an electronic system that includes a voltage regulator (VR) die that has bidirectional current flow, in accordance with an embodiment.

FIG. 2A is a cross-sectional illustration of an electronic system with a VR die that utilizes a unidirectional current flow, in accordance with an embodiment.

FIG. 2B is a plan view illustration of the electronic system in FIG. 2A with the system-on-a-chip (SoC) die omitted for clarity, in accordance with an embodiment.

FIG. 3 is a cross-sectional illustration of an electronic system with a VR die that utilizes a unidirectional current flow to provide a connection to an inductor provided in a package substrate, in accordance with an embodiment.

FIG. 4 is a cross-sectional illustration of an electronic system with a VR die that utilizes a unidirectional current flow and incorporates an integrated inductor, in accordance with an embodiment.

FIG. 5 is a cross-sectional illustration of an electronic system with a VR die that is embedded in the package substrate and utilizes a unidirectional current flow, in accordance with an embodiment.

FIG. 6 is a cross-sectional illustration of an electronic system with a VR die that utilizes a unidirectional current flow, in accordance with an embodiment.

FIG. 7 is a schematic of a computing device built in accordance with an embodiment.

### EMBODIMENTS OF THE PRESENT DISCLOSURE

Described herein are voltage regulator (VR) chiplets that have unidirectional current flow, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

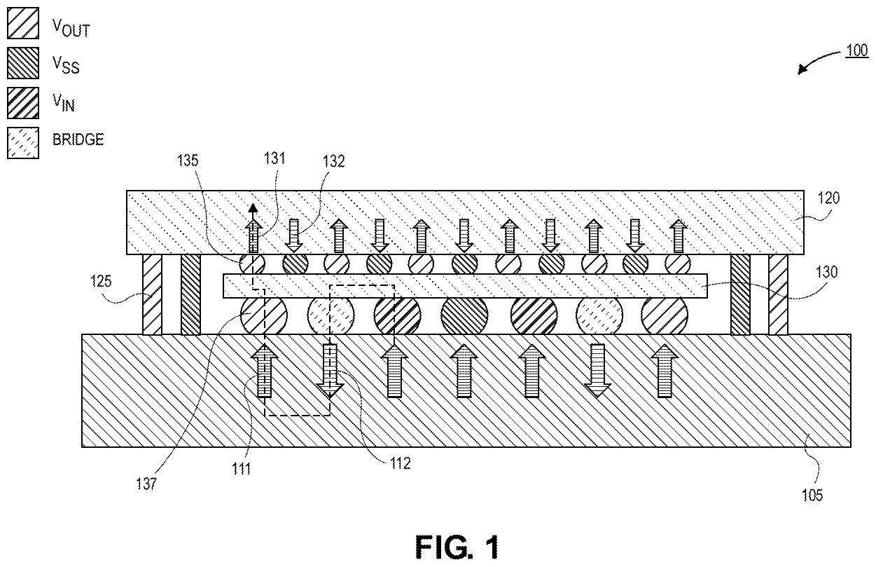

As noted above, when the voltage regulator (VR) is disaggregated from the system-on-a-chip (SoC), the footprint of the VR die is limited by the current carrying capability of the bumps. Despite the VR die requiring only a small footprint to accommodate the VR circuitry, a larger footprint is necessary in order to meet Iₘₐₓ requirements. An example of an electronic system 100 with such an architecture is provided in FIG. 1. The electronic system 100 may comprise a package substrate 105. A first die 120 is provided over the package substrate 105, and a VR die 130 is provided between the first die 120 and the package substrate 105. The first die 120 may be electrically coupled to the package substrate 105 through conductive pillars 125. The VR die 130 is electrically coupled to the first die 120 and the package substrate 105 by first bumps 135 and second bumps 137. For example, first bumps 135 connect the first die 120 to the VR die 130, and second bumps 137 connect the VR die 130 to the package substrate 105.

In FIG. 1, the shading of various components (e.g., pillars 125, bumps 135, and bumps 137) is used to indicate the signal that passes through the component. For example, the conductive pillars 125 carry V_{OUT} signals and V_{SS} signals, first bumps 135 carry V_{OUT} signals and V_{SS} signals, and second bumps 135 carry V_{OUT} signals, V_{SS} signals, V_{IN} signals, and bridge signals. A key that correlates the various shadings to the signals that are being carried is provided above the electronic system 100.

In FIG. 1, the current flow into/out of the VR die 130 is bidirectional. For example, a first current flow direction 131 flows out of the top surface of the VR die 130, and a second current flow direction 132 flows into the top surface of the VR die 130. Similarly, a third current flow direction 111 flows into the bottom surface of the VR die 130, and a fourth current flow direction 112 flows out of the bottom surface of the VR die 130.

In FIG. 1, the current feeding the VR die 130 is fed from the package substrate 205 through V_{IN} and V_{SS} second bumps 137. The current is fed through the switches (not shown) of the VR die 130 and the output from the switches goes back into the package inductors (not shown) through bridge second bumps 137. The current from the package inductors then is routed back up to the VR die 130 through the V_{OUT} second bumps 137. Additionally, with this implementation, the primary current flow path is all addressed through the package side second bumps 137.

As shown in FIG. 1, a large number of first bumps 135 and second bumps 137 are necessary in order to meet the Iₘₐₓ requirements for the electronic system 100. The large number of first bumps 135 and second bumps 137 is due, at least in part, to the inefficiency of a bidirectional current flow. That is, bumps 135 that facilitate current flow in the first direction 131 cannot handle the same amount of current as bumps 135 that facilitate current flow in the second direction 132. Similarly, bumps 137 that facilitate current flow in the third direction 111 cannot handle the same amount of current as bumps 137 that facilitate current flow in the fourth direction 112. Particularly, first bumps 135 and second bumps 137 can accommodate more current when the current flows in a top to bottom direction compared to the current that can be carrier by the first bumps 135 and the second bumps 137 in a bottom to top direction.

Due to the need to carry current in both the top to bottom direction and the bottom to top direction, the footprint of the VR die 130 needs to be expanded to accommodate additional first bumps 135 and second bumps 137 so that the I_{MAX} value is not exceeded. Furthermore, it is to be appreciated that the footprint of the VR circuitry is significantly smaller than the necessary footprint of the VR die 130. That is, the additional first bumps 135 and second bumps 137 needed to accommodate the I_{MAX} value result in an increase in the footprint. As such, the ability to remove first bumps 135 and second bumps 137 allows for a decrease in the overall footprint of the VR die 130.

Accordingly, embodiments include a VR die that comprises a unidirectional current flow. Particularly, the unidirectional current flow is from the top of the VR die to the bottom of the VR die. This takes advantage of the fact that bumps with current going down can handle significantly higher current than bumps where the current is going up. In addition to taking advantage of this asymmetry in current carrying capacity, embodiments disclosed herein also use the bumps on both sides of the VR die as part of the primary current flow path. The combination of these advantages, allow for the VR die size to be significantly smaller than what is shown in FIG. 1. For example, the reduction in area of the VR die may be up to approximately 50% compared to existing VR die solutions. Additionally, the number of bumps may be reduced by approximately 25% or more since both sides are used for current flow.

Shrinking the footprint of the VR die has several advantages. For one advantage, the reduced footprint allows for a decrease in the cost of the VR die. The decrease in cost can be attributed to the smaller amount of silicon that is needed to form the VR die. As such, more VR dies can be fabricated on a single wafer, and costs are reduced. Additionally, the reduction in size of the VR die results in a decrease in the cantilevering effect that results from having to propagate current along a longer distance.

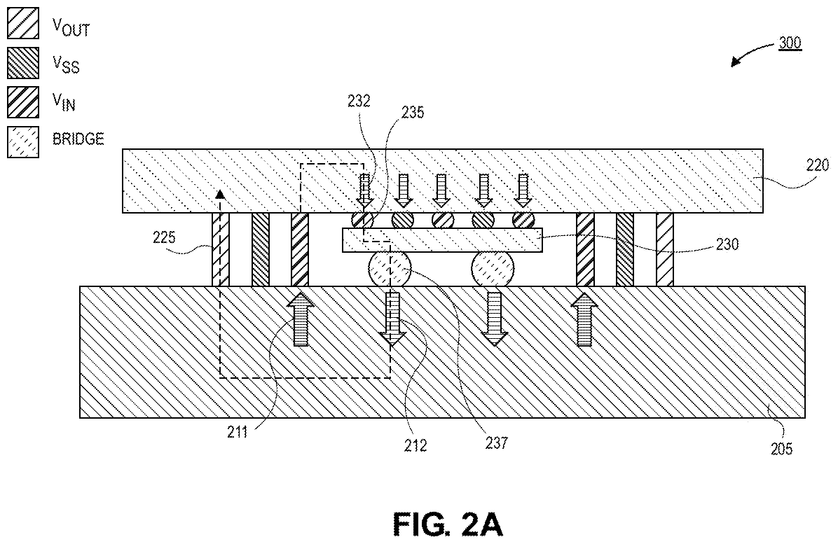

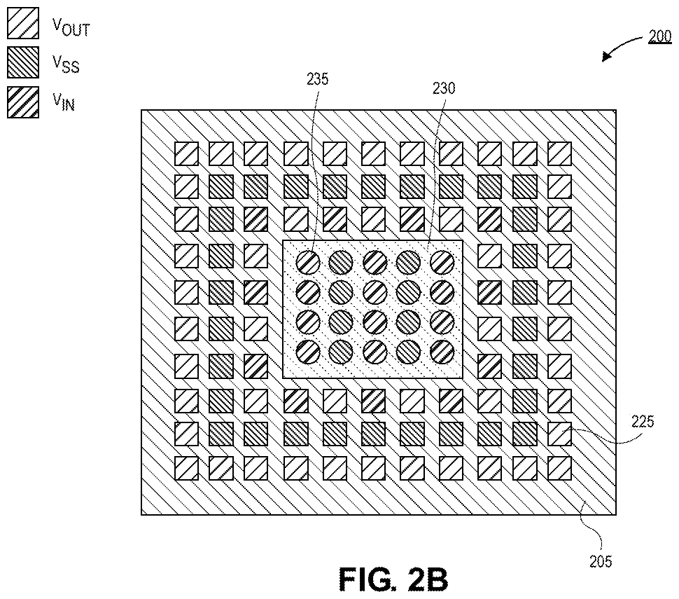

Referring now to FIG. 2A, a cross-sectional illustration of an electronic system 200 is shown, in accordance with an embodiment. In an embodiment, the electronic system 200 comprises a package substrate 205. In an embodiment, the package substrate 205 comprises a plurality of insulating layers with conductive features (not shown) embedded therein. In an embodiment, the conductive features may include conductive traces, pads, vias, etc. that provide electrical routing within the package substrate 205. In an embodiment, the package substrate 205 comprises a core. In other embodiments, the package substrate 205 is a coreless package substrate 205. In an embodiment, one or more inductors (not show) used by the VR die 230 may be provided in the package substrate 205.

In an embodiment, the electronic system 200 may further comprise a first die 220. The first die 220 may comprise an SoC, though other die types may also be included. The first die 220 may be the recipient of the power supplied by the VR die 230. In an embodiment, the VR die 230 may comprise circuitry configured to enable voltage regulation (e.g., voltage stepdown) necessary for the functioning of the first die 220. The active circuitry may be implemented on the VR die 230, and passive components (e.g., inductors, transformers, etc.) may be implemented on the package substrate 205.

In an embodiment, the first die 220 may be electrically coupled to the package substrate 205 by any suitable interconnect architecture. For example, conductive pillars 225 are show as one embodiment. Conductive pillars 225 allow for a high current capacity. Conductive pillars are typically characterized by having a high aspect ratio (e.g., height to width) and a substantially constant width through the height of the pillar 225. As indicated by the shading, the conductive pillars 225 may comprise V_{OUT} pillars 225, V_{SS} pillars 225, and V_{IN} pillars 225. In an embodiment, the pillars 225 comprise copper or the like. In an embodiment, the pillars 225 are provided outside of a footprint of the VR die 230.

In an embodiment, the VR die 230 is positioned between the first die 220 and the package substrate 205. The VR die 230 has a footprint that is smaller than a footprint of the first die 220. In a particular embodiment, the VR die 230 is entirely within the footprint of the first die 220, as shown in FIG. 2A. In an embodiment, the VR die 230 is electrically coupled to the first die 220 by first bumps 235, and the VR die 230 is electrically coupled to the package substrate 205 by second bumps 237. In an embodiment, the first bumps 235 may comprise V_{SS} first bumps 235 and V_{IN} first bumps 235. In an embodiment, the second bumps 237 may comprise bridge second bumps 237. In an embodiment, the first bumps 235 and the second bumps 237 may be any suitable bumping architecture. For example, the first bumps 235 and the second bumps 237 may be microbumps or the like. The first bumps 235 and the second bumps 237 may comprise solder balls.

In an embodiment, current from the package substrate 205 is fed up into the first die 220 by V_{IN} pillars 225, as indicated by current direction arrows 211. That is, current supplied in the vertical direction from the package substrate 205 to the first die 220 is supplied outside of the footprint of the VR die 230. As such, moving current through first bumps 235 and/or second bumps 237 from bottom up is avoided. Instead, bottom up current is delivered along conductive pillars 225 that are able to support higher currents.

In an embodiment, input current in the first die 220 is then fed into the top of the VR die 230 through the first V_{SS} bumps 235 and the first V_{IN} bumps 235, as indicated by current direction arrows 232. This current feeds the switches in the VR circuitry. In an embodiment, output from the switches is routed to the package inductors (not shown) through the bridge second bumps 237, as indicated by current direction arrows 212.

In such an embodiment, all of the current entering and exiting the VR die 230 is oriented from top to bottom. That is, current direction arrows 232 and 212 are directed towards the package substrate 205. Such an embodiment may be referred to as a unidirectional current flow since the current entering and exiting the VR die 230 is propagating in a single direction (i.e., towards the package substrate). The unidirectional current flow takes advantage of the asymmetric current carrying limitations of the bumps by providing current flow in the direction with the higher current carrying capacity. As such, the number of first bumps 235 and second bumps 237 may be reduced.

Additionally, such an embodiment utilizes bumps on both sides of the VR die 230 to provide the primary current flow path. That is, the primary current flow path enters the first bumps 235, passes through the VR die 230, and exits through the second bumps 237. This is in contrast to the embodiment described above with respect to FIG. 1, where the primary current flow path enters and exits the VR die 130 from only the second bumps 137. As such, the number of first bumps 235 and second bumps 237 may be reduced. The elimination of first bumps 235 and second bumps 237 reduces the necessary footprint of the VR die 230, and therefore, reduces the cost of the VR die 230. In addition to reducing costs of the VR die 230 by shrinking the size of the VR die 230, configurations with a reduced VR die footprint reduce the IR drop due to the cantilevering effect of having a large VR chiplet.

Referring now to FIG. 2B, a plan view illustration of the electronic system 200 in FIG. 2A is shown, in accordance with an embodiment. In the illustrated embodiment, the first die 220 is removed in order to expose the underlying features. As shown, a plurality of pillars 225 surround the VR die 230. In an embodiment, the V_{IN} pillars 225 may be immediately adjacent to the VR die 230. In some embodiments, the V_{IN} pillars 225 may be in an alternating pattern with V_{OUT} pillars 225.

Those skilled in the art will appreciated that various investigatory operations may be utilized to detect that various embodiments disclosed herein have been implemented in a given device. For example, it may be shown in cross-sectional analysis that the bottom second bumps 237 are bridge bumps that are directly coupled to one or more passive components, such as inductors, transformers, etc. That is, the bottom second bumps 237 may not be coupled to V_{IN} or V_{SS} sources. Additionally, analysis of the nets (e.g., by using an oscilloscope or the like) can be used to determine the polarity of the nets used to connect to the VR die 230. For example, various embodiments disclosed herein may be identified when it can be shown that current is only fed into the VR die 230 from above and current only exits the VR die 230 from below.

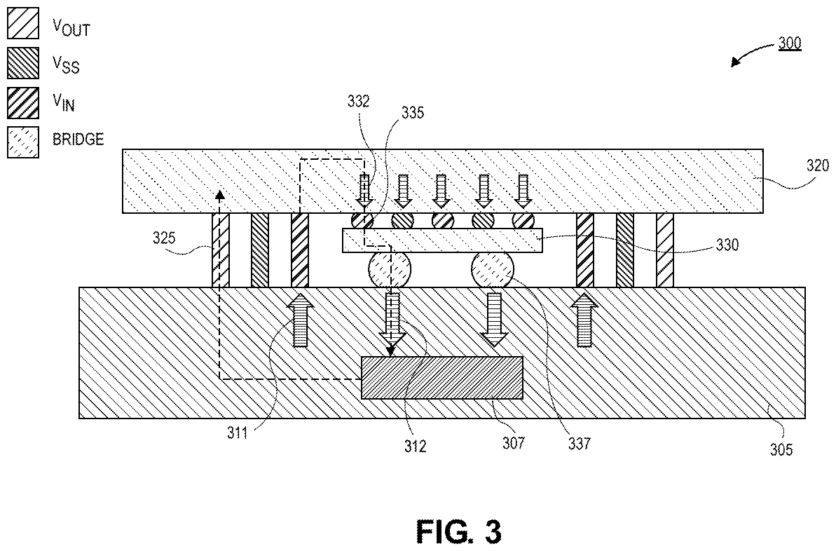

Referring now to FIG. 3, a cross-sectional illustration of an electronic system 300 is shown, in accordance with an embodiment. As shown in FIG. 3, the electronic system 300 comprises a package substrate 305. In an embodiment, the package substrate 305 may be substantially similar to the package substrate 205 described above. However, as shown in FIG. 3, a passive device 307 is embedded in the package substrate 305. In an embodiment, the passive device 307 may comprise passive components configured to be used as part of the voltage regulation system that supplies power to the first die 320. For example, the passive device 307 may comprise one or more inductors and/or transformers. In an embodiment, the passive device 307 may be embedded in insulating layers of the package substrate 305. In other embodiments, the passive device 307 may be embedded in a core of the package substrate 305.

In an embodiment, the passive device 307 may comprise a plurality of passive devices. In some embodiments, the passive devices 307 are integrated into the package substrate 305. For example, the passive devices 307 may be fabricated during the process flow used to form the package substrate 305. In other embodiments, the passive device 307 is a discrete module. The discrete module may be embedded in one or more of the layers of the package substrate 305.

In an embodiment, the passive device 307 may comprise passives with any suitable architecture. For example, in the case of an inductor, the passive device 307 may comprise, but is not limited to, an air core inductor (ACI), a magnetic core inductor (MCI), a coaxial metal inductor loop (coax MIL), or a planar metal inductor loop (planar MIL). In some embodiments, the passive device 307 may comprise a combination of different passive architectures.

In an embodiment, the electronic system 300 may further comprise a first die 320. The first die 320 may be substantially similar to the first die 220 described above. For example, the first die 320 may comprise an SoC. The first die 320 may be the recipient of the power supplied by the VR die 330. In an embodiment, the VR die 330 may comprise circuitry configured to enable voltage regulation (e.g., voltage stepdown) necessary for the functioning of the first die 320. The active circuitry may be implemented on the VR die 330, and active circuitry may be coupled to the passive devices 307 embedded in the package substrate 305.

In an embodiment, the first die 320 may be electrically coupled to the package substrate 305 by conductive pillars 325. As indicated by the shading, the conductive pillars 325 may comprise V_{OUT} pillars 325, V_{SS} pillars 325, and V_{IN} pillars 325. Current direction arrow 311 indicates that current from the package substrate 305 to the first die 320 passes through the V_{IN} pillars 325 in a bottom up direction.

In an embodiment, the VR die 330 is positioned between the first die 320 and the package substrate 305. The VR die 330 has a footprint that is smaller than a footprint of the first die 320. In an embodiment, the VR die 330 is electrically coupled to the first die 320 by first bumps 335, and the VR die 330 is electrically coupled to the package substrate 305 by second bumps 337. Similar to the embodiment described above, the first bumps 335 may comprise V_{SS} first bumps 335 and V_{IN} first bumps 335, and the second bumps 337 may comprise bridge second bumps 337.

In such an embodiment, all of the current entering and exiting the VR die 330 is oriented from top to bottom. That is, current direction arrows 332 and 312 are directed towards the package substrate 305. Such an embodiment may be referred to as a unidirectional current flow since the current entering and exiting the VR die 230 is propagating in a single direction (i.e., towards the package substrate 305). The unidirectional current flow takes advantage of the asymmetric current carrying limitations of the bumps by providing current flow in the direction with the higher current carrying capacity. As such, the number of first bumps 335 and second bumps 337 may be reduced.

Additionally, such an embodiment utilizes bumps on both sides of the VR die 330 to provide the primary current flow path. That is, the primary current flow path enters the first bumps 335, passes through the VR die 330, and exits through the second bumps 337. As such, the number of first bumps 335 and second bumps 337 may be reduced. The elimination of first bumps 335 and second bumps 337 reduces the necessary footprint of the VR die 330, and therefore, reduces the cost of the VR die 330. In addition to reducing costs of the VR die 330 by shrinking the size of the VR die 330, configurations with a reduced VR die footprint reduce the IR drop due to the cantilevering effect of having a large VR chiplet.

As shown in FIG. 3, the current that is supplied to the passive devices 307 is then routed to the V_{OUT} pillars 325. Accordingly, the current can then be provided to the first die 320 by the V_{OUT} pillars 325. It is to be appreciated that the current path from the passive devices 307 to the first die 320 is entirely outside of the VR die 330. As such, there is no need for current that passes through the VR die 330 that has a bottom up current direction.

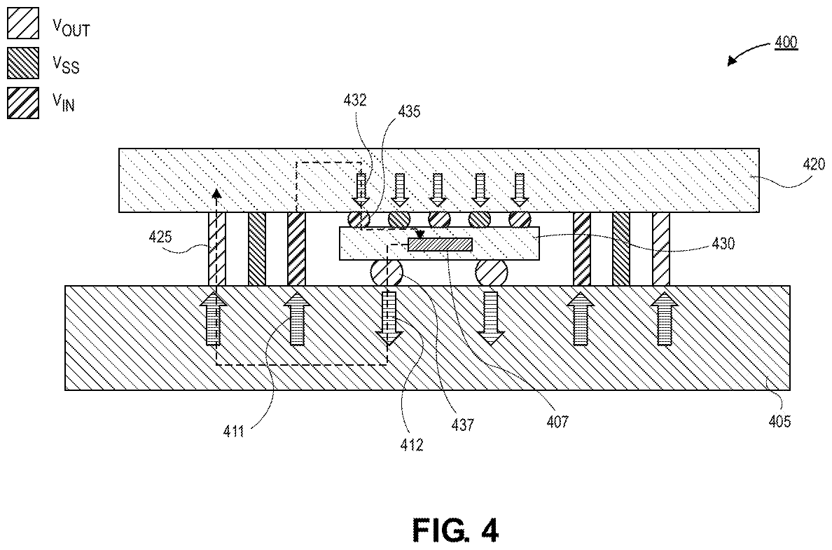

Referring now to FIG. 4, a cross-sectional illustration of an electronic system 400 is shown, in accordance with an embodiment. The electronic system 400 in FIG. 4 is substantially similar to the electronic system 300 in FIG. 3, with the exception that the passive devices 407 are moved from the package substrate 405 to the VR die 430. For example, the electronic system 400 comprises a package substrate 405, a first die 420, and a VR die 430. Current direction arrow 411 illustrates a bottom up current direction through V_{IN} pillars 425 into the first die 420. Current direction arrows 432 illustrate current from the first die 420 passing through first bumps 435 into the VR die 430.

Since the passive devices 407 are provided in the VR die 430, the second bumps 437 may be V_{OUT} second bumps 437 instead of bridge second bumps 437. The current (as indicated by current direction arrows 412) is sent into the package substrate 405. The output current from the V_{OUT} second bumps 437 may be propagated along the package substrate 405 and sent up the V_{OUT} pillars 425 back into the first die 420. As such, there is no current that flows through the VR die 430 that has a bottom up current direction. This allows for a reduction in the number of first bumps 435 and second bumps 437. As such, costs are reduced, and the cantilevering effect of a large VR die 430 is avoided.

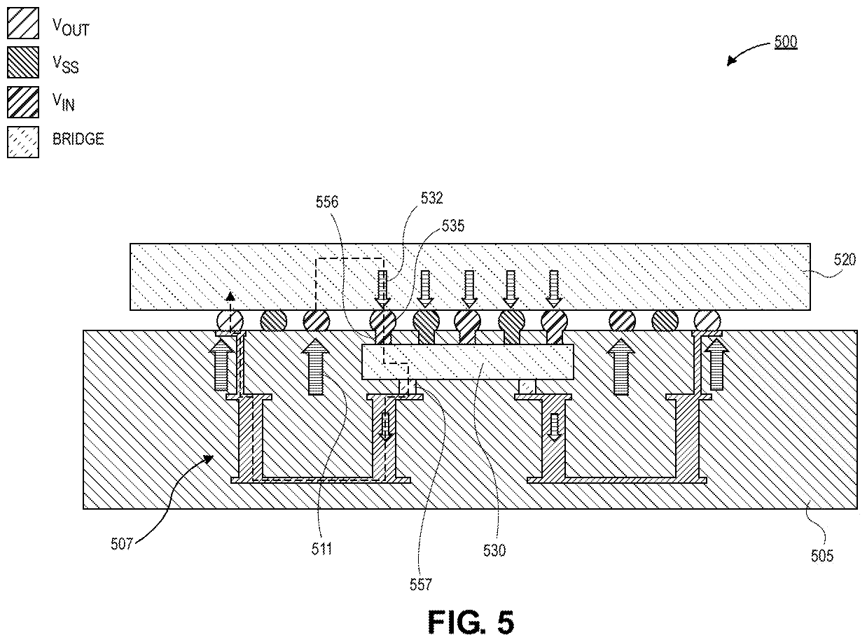

Referring now to FIG. 5, a cross-sectional illustration of an electronic system 500 is shown, in accordance with an additional embodiment. In an embodiment, the electronic system 500 utilizes an embedded die architecture. Particularly, the VR die 530 is embedded into the package substrate 505. In such an embodiment, the first die 520 may be electrically coupled to the package substrate 505 and the VR die 530 by first bumps 535. The first bumps 535 may comprise V_{OUT} first bumps 535, V_{SS} first bumps 535, and V_{IN} first bumps 535.

In an embodiment, the current path may begin in the package substrate 505 and go up through a V_{IN} first bump 535 (as indicated by current direction arrow 511). The current may then proceed down a V_{IN} first bump 535 to a pad 556 on the VR die 530 (as indicated by current direction arrow 532). The current may then pass through the circuitry of the VR die 530 and exit the bottom of the VR die 530 through a bridge pad 557. In an embodiment, the bridge pad 557 is electrically coupled to a passive device 507. For example, an inductor loop in the package substrate 505 is illustrated as the passive device 507. However, it is to be appreciated that any passive device, such as those described above, may be connected to the bridge pad 557. After exiting the passive device 507, the current enters the first die 520 through a V_{OUT} first bump 535.

Accordingly, the current that passes through the VR die 530 is unidirectional. That is, the current enters the VR die 530 from a top surface of the VR die 530 and exits the VR die 530 from a bottom surface of the VR die 530. Furthermore, it is to be appreciated that the direction of the unidirectional current flow is top to bottom. As such, the current carrying asymmetry of the first bumps 535 is harnessed in order to allow for an increased current flow. This allows for the number of first bumps 535 over the VR die 530 to be reduced. Accordingly, the necessary footprint of the VR die 530, and the cost of the VR die 530 is reduced. In addition to reducing costs of the VR die 530 by shrinking the size of the VR die 530, configurations with a reduced VR die footprint reduce the IR drop due to the cantilevering effect of having a large VR chiplet.

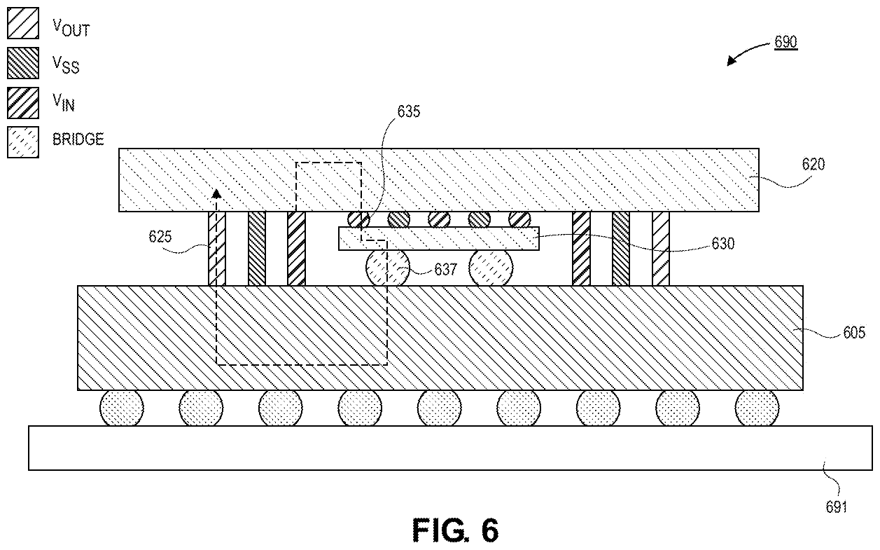

Referring now to FIG. 6, a cross-sectional illustration of an electronic system 690 is shown, in accordance with an embodiment. The electronic system 690 may be substantially similar to any of the electronic systems described above, with the exception of the addition of a board 691 below the package substrate 605. The board 691 may be a printed circuit board (PCB), a motherboard, or the like.

In the particular embodiment shown in FIG. 6, the electronic system 690 includes a package substrate 605, a first die 620, and a VR die 630 that has an architecture that is similar to the architecture of the electronic system 200 in FIG. 2A. For example, the current path through the VR die 630 is unidirectional with a current direction that is a top to bottom current direction. Particularly, current passes through V_{IN} pillars 625 into the first die 620. Current then proceeds into the top of the VR die 630 through a V_{IN} first bumps 635. The current passes through integrated circuitry of the VR die 630 and exits a bottom of the VR die 630 through a bridge second bump 637. The current is then routed through the package substrate 605 to a V_{OUT} pillar 625 and passes back into the first die 620. As such, the current passing in a bottom up direction only passes through the pillars 625. That is, there is no bottom up current that passes into the VR die 630.

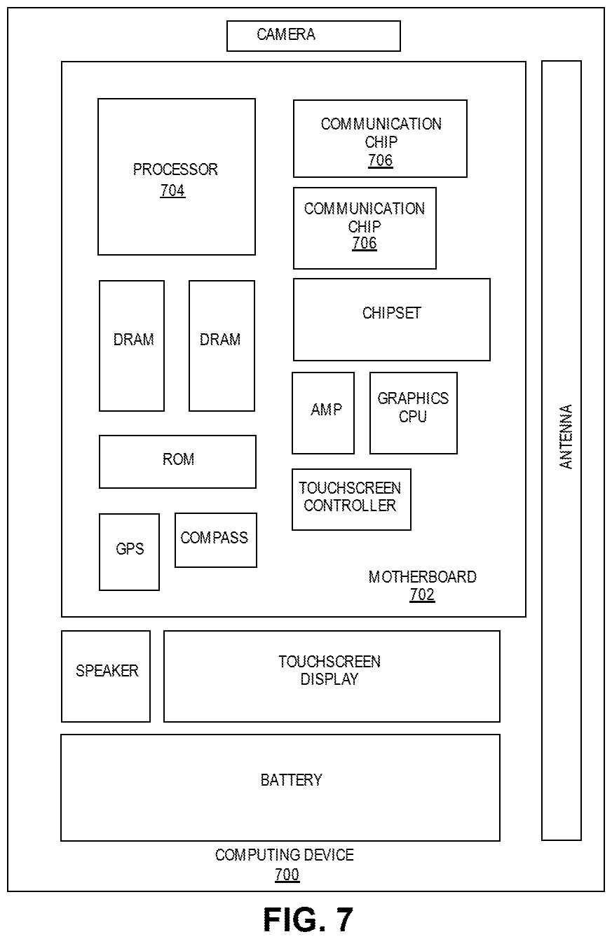

FIG. 7 illustrates a computing device 700 in accordance with one implementation of the invention. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations, the integrated circuit die of the processor may be coupled to an electronic package that comprises a VR die that has a unidirectional current flow that is from a top surface of the VR die to a bottom surface of the VR die, in accordance with embodiments described herein. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the invention, the integrated circuit die of the communication chip may be coupled to an electronic package that comprises a VR die that has a unidirectional current flow that is from a top surface of the VR die to a bottom surface of the VR die, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic device, comprising: a package substrate; a first die electrically coupled to the package substrate; and a second die with a first surface facing the first die and second surface facing the package substrate that is electrically coupled to the package substrate and the first die, wherein the second die is between the package substrate and the first die, wherein the second die comprises voltage regulation (VR) circuitry, and wherein current is received by the second die through only the first surface and the current only exits the second die through the second surface.

Example 2: the electronic device of Example 1, wherein the second die is electrically coupled to an inductor embedded in the package substrate.

Example 3: the electronic device of Example 2, wherein the inductor is electrically coupled to the first die through an interconnect that passes outside of the second die.

Example 4: the electronic device of Examples 1-3, wherein the first die is electrically coupled to the package substrate by conductive pillars, wherein the conductive pillars are provided outside of the second die.

Example 5: the electronic device of Example 4, wherein conductive pillars immediately adjacent to the second die are configure for providing a V_{IN} signal to the first die.

Example 6: the electronic device of Example 4, wherein the second die is electrically coupled to the first die by first solder balls over a top surface of the second die, and wherein the second die is electrically coupled to the package substrate by second solder balls over a bottom surface of the second die.

Example 7: the electronic device of Example 6, wherein the current through the second die passes from the first solder balls to the second solder balls.

Example 8: the electronic device of Example 6 or Example 7, wherein individual ones of the second solder balls are electrically coupled to only an inductor.

Example 9: the electronic device of Example 8, wherein the inductor comprises an air core inductor, a magnetic core inductor, a coaxial metal inductor loop, or a planar metal inductor loop.

Example 10: the electronic device of Examples 6-9, wherein the first solder balls are configured to provide a V_{IN} input and a V_{SS} input to the second die.

Example 11: the electronic device of Examples 1-10, wherein the second die further comprises: an inductor integrated into the second die.

Example 12: the electronic device of Example 11, wherein interconnects between the second die and the package substrate are configured to provide a V_{OUT} signal.

Example 13: the electronic device of Examples 1-12, wherein a footprint of the first die is larger than a footprint of the second die, and wherein the second die is entirely within the footprint of the first die.

Example 14: an electronic device, comprising: a package substrate, wherein the package substrate comprises an inductor; a first die over the package substrate, wherein the first die is a system-on-a-chip (SoC); and a second die with a first surface and a second surface, wherein the second die is a voltage regulation (VR) die, wherein current enters the second die from the first surface and exits the second die from the second surface, and wherein the second die is electrically coupled to the first die and the inductor.

Example 15: the electronic device of Example 14, wherein the second die is between the first die and the package substrate.

Example 16: the electronic device of Example 14, wherein the second die is embedded in the package substrate.

Example 17: the electronic device of Examples 14-16, wherein the first die has a first footprint, and wherein the second die has a second footprint, and wherein the second footprint is entirely within the first footprint.

Example 18: the electronic device of Examples 14-17, wherein the first die is electrically coupled to the package substrate by a plurality of conductive pillars.

Example 19: the electronic device of Example 18, wherein the conductive pillars are arranged around a perimeter of the second die.

Example 20: the electronic device of Examples 14-19, wherein solder balls on the first surface of the second die are configured to receive V_{IN} and V_{SS} inputs.

Example 21: the electronic device of Examples 14-20, wherein the inductor is electrically coupled to the first die by a conductive pillar.

Example 22: a voltage regulator (VR) chiplet, comprising: a semiconductor substrate with a first surface and a second surface; integrated circuitry on the semiconductor substrate configured to provide a conversion of an input voltage to an output voltage; and wherein the first surface is configured to only receive current, and wherein the current is only to exit the semiconductor substrate through the second surface.

Example 23: the VR chiplet of Example 22, further comprising: an inductor integrated into the VR chiplet.

Example 24: an electronic system, comprising: a board; a package substrate coupled to the board, wherein the package substrate comprises an inductor; a first die over the package substrate, wherein the first die is a system-on-a-chip (SoC); and a second die coupled to the package substrate and the first die, wherein the second die comprises a first surface and a second surface, wherein the second die is a voltage regulation (VR) die, and wherein current enters the second die from the first surface and exits the second die from the second surface.

Example 25: the electronic system of Example 24, wherein the second die is embedded in the package substrate, or the second die is between the first die and the package substrate.

What is claimed is:

1. An electronic device, comprising:
a package substrate;
a first die electrically coupled to the package substrate; and
a second die with a first surface facing the first die and second surface facing the package substrate that is electrically coupled to the package substrate and the first die, wherein the second die is between the package substrate and the first die, wherein the second die comprises voltage regulation (VR) circuitry, and wherein current is received by the second die through only the first surface and the current only exits the second die through the second surface.

2. The electronic device of claim 1, wherein the second die is electrically coupled to an inductor embedded in the package substrate.

3. The electronic device of claim 2, wherein the inductor is electrically coupled to the first die through an interconnect that passes outside of the second die.

4. The electronic device of claim 1, wherein the first die is electrically coupled to the package substrate by conductive pillars, wherein the conductive pillars are provided outside of the second die.

5. The electronic device of claim 4, wherein conductive pillars immediately adjacent to the second die are configure for providing a V_{IN} signal to the first die.

6. The electronic device of claim 4, wherein the second die is electrically coupled to the first die by first solder balls over a top surface of the second die, and wherein the second die is electrically coupled to the package substrate by second solder balls over a bottom surface of the second die.

7. The electronic device of claim 6, wherein the current through the second die passes from the first solder balls to the second solder balls.

8. The electronic device of claim 6, wherein individual ones of the second solder balls are electrically coupled to only an inductor.

9. The electronic device of claim 8, wherein the inductor comprises an air core inductor, a magnetic core inductor, a coaxial metal inductor loop, or a planar metal inductor loop.

10. The electronic device of claim 6, wherein the first solder balls are configured to provide a V_{IN} input and a V_{SS} input to the second die.

11. The electronic device of claim 1, wherein the second die further comprises:
an inductor integrated into the second die.

12. The electronic device of claim 11, wherein interconnects between the second die and the package substrate are configured to provide a V_{OUT} signal.

13. The electronic device of claim 1, wherein a footprint of the first die is larger than a footprint of the second die, and wherein the second die is entirely within the footprint of the first die.

14. An electronic device, comprising:
a package substrate, wherein the package substrate comprises an inductor;
a first die over the package substrate, wherein the first die is a system-on-a-chip (SoC); and
a second die with a first surface and a second surface, wherein the second die is a voltage regulation (VR) die, wherein current enters the second die from the first surface and exits the second die from the second surface, and wherein the second die is electrically coupled to the first die and the inductor.

15. The electronic device of claim 14, wherein the second die is between the first die and the package substrate.

16. The electronic device of claim 14, wherein the second die is embedded in the package substrate.

17. The electronic device of claim 14, wherein the first die has a first footprint, and wherein the second die has a second footprint, and wherein the second footprint is entirely within the first footprint.

18. The electronic device of claim 14, wherein the first die is electrically coupled to the package substrate by a plurality of conductive pillars.

19. The electronic device of claim 18, wherein the conductive pillars are arranged around a perimeter of the second die.

20. The electronic device of claim 14, wherein solder balls on the first surface of the second die are configured to receive V_{IN} and V_{SS} inputs.

21. The electronic device of claim 14, wherein the inductor is electrically coupled to the first die by a conductive pillar.

22. A voltage regulator (VR) chiplet, comprising:
a semiconductor substrate with a first surface and a second surface;
integrated circuitry on the semiconductor substrate configured to provide a conversion of an input voltage to an output voltage; and
wherein the first surface is configured to only receive current, and wherein the current is only to exit the semiconductor substrate through the second surface.

23. The VR chiplet of claim 22, further comprising:
an inductor integrated into the VR chiplet.

24. An electronic system, comprising:
a board;
a package substrate coupled to the board, wherein the package substrate comprises an inductor;
a first die over the package substrate, wherein the first die is a system-on-a-chip (SoC); and
a second die coupled to the package substrate and the first die, wherein the second die comprises a first surface and a second surface, wherein the second die is a voltage regulation (VR) die, and wherein current enters the second die from the first surface and exits the second die from the second surface.

25. The electronic system of claim 24, wherein the second die is embedded in the package substrate, or the second die is between the first die and the package substrate.
